(19) United States
(12) Patent Application Publication
(10) Pub. No.: US 2011/0165016 A1
(43) Pub. Date: Jul. 7, 2011

(54) REFLECTIVE FILM FOR OPTICAL INFORMATION RECORDING MEDIUM AND SPUTTERING TARGET FOR FORMING REFLECTIVE FILM FOR OPTICAL INFORMATION RECORDING MEDIUM

(75) Inventors: Norihiro Jiko, Hyogo (JP); Junichi Nakai, Hyogo (JP); Yuuki Tauchi, Hyogo (JP)

(73) Assignee: Kabushiki Kaisha Kobe Seiko Sho (Kobe Steel, Ltd.), Kobe-shi, Hyogo (JP)

(21) Appl. No.: 13/062,384

(22) PCT Filed: Sep. 3, 2009
(86) PCT No.: PCT/JP2009/065431

§ 371 Date: Mar. 4, 2011

(30) Foreign Application Priority Data
Sep. 5, 2008 (JP) 2008-228902

(51) Int. Cl. C22C 21/00; C23C 14/34

(52) U.S. Cl. 420/552; 204/298.13; 420/528

(57) ABSTRACT

Provided is an Al-based alloy reflective film which reduces noise on an optical information recording medium by having a reflective film surface accurately reproduce grooves, pits and the like formed on a substrate, and has high reflectivity. A sputtering target which is effective for forming such a reflective film is also provided. The reflective film to be used for the optical information recording medium is substantially composed of an Al-based alloy containing 2.0-15.0 atm % of a rare-earth element, and has a crystallite size of 30 nm or smaller in the thickness direction of the reflective film.

### TECHNICAL FIELD

The present invention relates to a reflective film for use in an optical information recording medium such as DVD-ROM, DVD-R, DVD+R, DVD-RW, DVD+RW, DVD-RAM, BD (blue-ray disk)-R, BD-RE, or BD-ROM, and a sputtering target for forming such a reflective film.

### BACKGROUND ART

The optical information recording media (optical disks) are largely classified into three types of read-only type (e.g., DVD-ROM and BD-ROM), write-once read-many type (e.g., DVD-R, DVD+R, and BD-R), and rewritable type (e.g., DVD-RW, DVD+RW, BD-RE, and DVD-RAM) according to the recording and reproduction system.

Out of these, for example, the read-only type optical information recording medium has a configuration in which on a transparent plastic or other substrate, a reflective film containing Ag, Al, or the like as a main component, and a light transmission layer are successively stacked. Further, one layer of a reflective film and one layer of light transmission layer are basically formed, but there is also known the one in which two layers of each are formed.

The optical information recording medium includes a layer structure according to the recording and reproduction system. However, even when any recording and reproduction system is adopted, the layer structure basically includes the reflective film as described above. As materials for such a reflective film, Au, Cu, Ag, Al, and alloys including them as main components have been used in many ways.

Out of these, a reflective film of an Au-based alloy containing Au as a main component has advantages of excellent chemical stability (durability), and less change with time of the recording characteristics, but is very expensive. Further, the reflective film cannot unfavorably provide a sufficiently high reflectivity with respect to a blue laser (wavelength 405 nm) for use in recording and reproduction of BD or HD DVD. A Cu-based alloy containing Cu as a main component is low-priced, but is poorest in durability among conventional reflective film materials. Further, as with Au, the Cu-based alloy has a defect of low reflectivity with respect to a blue laser, and has limited uses. In contrast, the reflective film of an Ag-based al lay containing Ag as a main component exhibits a sufficiently high reflectivity within the range of 400 to 800 nm of the practical wavelength region, and is also excellent in durability. For this reason, the reflective film has been widely used as an optical disk using a blue layer.

On the other hand, it is known that a reflective film of an Al-based alloy containing Al as a main component is low-priced, and has a sufficiently high reflectivity at a wavelength of 405 nm. For this reason, the reflective film has been widely used as with the Ag-based alloy.

Incidentally, the reflective film of an optical information recording medium is required to have a characteristic of high reflectivity. In addition, the reflective film is also required to reduce the noise of the recording medium as the characteristics. As those for forming reflective films satisfying such required characteristics, various Al-based alloys have been proposed up to now. For example, PTL 1 discloses an Al-based alloy containing Cr, Fe, and Ti in amounts of 1 to 4%, respectively. It is proposed as follows: such an alloy composition provides a reflective film which is high in reflectivity, has a smooth surface (about 5 to 10 nm in Ra), shows a small growth of crystal grains with a change in temperature, and shows a small change in reflectivity.

With the chemical component composition shown in the technology, the reflectivity of the reflective film is enhanced. However, the crystallite size (crystal grain size) is not necessarily reduced. Thus, the reflective film surface unfavorably does not reproduce grooves or pits formed in the substrate with precision. Under such conditions, the optical information recording medium using the reflective film has a larger noise, and cannot provide a favorable signal quality.

### CITATION LIST

### [Patent Literature]

[PTL 1] JP-A-2007-092153

### DISCLOSURE OF THE INVENTION

### Problem to be Solved by the Invention

The present invention was made in view of the foregoing circumstances. It is an object of the present invention to provide an Al-based alloy reflective film whose reflective film surface can reproduce grooves, pits, or the like formed in a substrate with precision, and which can reduce the noise of an optical information recording medium, and has a high reflectivity, and a sputtering target useful for forming such a reflective film.

### Means for Solving the Problem

The gist of the present invention will be shown below.

(1) A reflective film for optical information recording medium for use in an optical information recording medium, the reflective film substantially including an Al-based alloy containing a rare earth element in an amount of 2.0 to 15.0 at %, wherein the crystallite size in the thickness direction of the reflective film is 30 nm or less.

(2) A reflective film for optical information recording medium for use in an optical information recording medium, the reflective film substantially including an Al-based alloy containing a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %, wherein the crystallite size in the thickness direction of the reflective film is 30 nm or less.

(3) A sputtering target for forming a reflective film for an optical information recording medium for forming a reflective film for use in an optical information recording medium, the sputtering target substantially including an Al-based alloy containing a rare earth element in an amount of 2.0 to 15.0 at %.

(4) A sputtering target for forming a reflective film for an optical information recording medium for forming a reflective film for use in an optical information recording medium, the sputtering target substantially including an Al-based alloy containing a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %.

The reflective film for optical information recording medium of the item (1) is preferably a reflective film for optical information recording medium for use in an optical information recording medium. The reflective film is a reflective film for optical information recording medium including an Al-based alloy containing a rare earth element in an amount of 2.0 to 15.0 at %, wherein the crystallite size in the thickness direction of the reflective film is 30 nm or less.

The reflective film for optical information recording medium of the item (2) is preferably a reflective film for optical information recording medium for use in an optical information recording medium. The reflective film is a reflective film for optical information recording medium including an Al-based alloy containing a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %, wherein the crystallite size in the thickness direction of the reflective film is 30 nm or less.

The sputtering target for forming a reflective film for an optical information recording medium of the item (3) is preferably a sputtering target for forming a reflective film for an optical information recording medium for forming a reflective film for use in an optical information recording medium. The sputtering target is a sputtering target for forming a reflective film for an optical information recording medium including an Al-based alloy containing a rare earth element in an amount of 2.0 to 15.0 at %.

The sputtering target for forming a reflective film for an optical information recording medium of the item (4) is preferably a sputtering target for forming a reflective film for an optical information recording medium for forming a reflective film for use in an optical information recording medium. The sputtering target is a sputtering target for forming a reflective film for an optical information recording medium including an Al-based alloy containing a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %.

### Effect of the Invention

In accordance with the present invention, it is possible to implement a reflective film which can reduce the noise of an optical information recording medium, and has a high reflectivity. An optical information recording medium having such a reflective film is very useful for a further improvement of the recording characteristics.

### BRIEF DESCRIPTION OF THE DRAWINGS

FIGS. 1(a) to 1(d) are figure-substitute transmission electron microphotographs showing the cross-sectional structures of various Al-based alloy reflective films, in which FIG. 1(a) shows a figure-substitute transmission electron microphotograph in the case of pure Al (sample No. 1 of Table 1), FIG. 1(b) shows a figure-substitute transmission electron microphotograph in the case of Al-8.2% Ti (sample No. 6 of Table 1), FIG. 1(c) shows a figure-substitute transmission electron microphotograph in the case of Al-5.9% Nd-1.4% Ta (sample No. 38 of Table 2), and FIG. 1(d) shows a figure-substitute transmission electron microphotograph in the case of Al-8.7% Nd (sample No. 20 of Table 2); and

FIG. 2 is a graph showing the relationship between the frequency and noises in BD-R disks manufactured using various Al alloy reflective films.

### BEST MODE FOR CARRYING OUT THE INVENTION

In order to attain the foregoing object, the present inventors particularly conducted a study from various angles on an Al-based alloy which can be a material for a reflective film capable of keeping a sufficiently high reflectivity, and minimizing the noise of a recording medium. As a result, the present inventors found the following fact: when a reflective film includes an Al-based alloy containing a proper amount of a rare earth element, or an Al-based alloy containing a proper amount of an alloy element such as Ti, V, Cr, Nb, Mo, Hf, Ta, or W (the element may be hereinafter referred to as a “refractory metal element”) with the rare earth element, it is possible to minimize the crystallite size (the crystal grain size in the direction of the reflective film thickness) while keeping the reflectivity in a sufficiently high state. This can minimize the noise of the optical information recording medium. Thus, the present invention was completed. Below, the operational effects of the present invention will be described along how the present invention was completed.

As reflective films, those using Al-based alloys containing Ti or Cr have already been proposed (PTL 1). However, the present inventors conducted a study on the characteristics as the reflective film for Al-based alloys containing refractory metal elements such as Nb, V, Mo, Hf, Ta, and W other than these elements.

As a result, the following fact has been revealed: with an Al-based alloy containing a refractory metal element, as the content of the refractory metal element increases, the crystallite size of the reflective film is reduced; however, the reflectivity is accordingly reduced. Namely, addition of a refractory metal element in an amount necessary for sufficiently reducing the crystallite size results in large reduction of the reflectivity. In other words, a refractory metal element such as Ti, V, Cr, Nb, Mo, Hf, Ta, or W produces an effect of reducing the crystallite size. However, the refractory metal element in such an amount as to be able to keep the reflectivity does not produce an effect of sufficiently reducing the crystallite size.

According to the study by the present inventors, the following fact has been revealed: in a reflective film including pure Al, large crystal grains are formed in the depth direction (thickness direction) and the transverse direction of the film: whereas, when an Al-based alloy containing only a refractory metal element is formed into a reflective film, the crystal grain size is reduced in the direction in parallel with the substrate plane, but is less likely to be reduced in a direction perpendicular to the substrate plane, resulting in formation of columnar crystal grains. In this case, the reflective film surface does not reproduce grooves or pits in the substrate with precision, resulting in an increase in noise in the reproduced signal. Such a state is not improved only by reducing the surface roughness of the reflective film, so that a drastic improvement of the crystal grain size is necessary.

The present inventors further conducted a continued study on an optimum Al-based alloy as a reflective film. As a result, the following has been revealed: when an Al-based alloy containing a proper amount of rare earth element is used as a reflective film, the crystallite size can be reduced both in the parallel direction and in the perpendicular direction (thickness direction) with respect to the substrate plane; this enhances the precision for the reflective film surface to reproduce the substrate shape; as a result, the noise can be reduced extremely, and reduction of the reflectivity is not caused within this proper amount range (i.e., the small crystallite size and the high reflectivity are compatible).

The proper amount of a rare earth element for allowing such an effect to be exhibited is 2.0 to 15.0% (meaning “at %”, for the chemical component, the same applies hereinafter). Namely, when the content of a rare earth element in the Al-based alloy is less than 2.0%, the crystallize size cannot be reduced sufficiently. Whereas, when the content exceeds 15.0%, the reflectivity becomes too low. Incidentally, the lower limit of the preferred content of a rare earth element is 3.0% (more preferably 4.0%), and the preferred upper limit thereof is 14.0% (more preferably 13.0%).

The rare earth elements for use in the Al-based alloy reflective film of the present invention mean an element group including Y (yttrium) other than lanthanoid series rare earth elements such as La, Ce, Pr, Nd, Sm, Eu, Gd, Tb, Dy, Ho, Tm, and Yb, and preferably La, Ce, Nd, Gd, and Dy. These may be used alone, or may be used in combination of two or more thereof.

Incidentally, with the Al-based alloys containing only refractory metal elements such as Ti, V, Cr, Nb, Mo, Hf, Ta, and W, it is difficult to achieve compatibility between the high reflectivity and refinement of the crystallite size. However, with the Al-based alloys containing refractory metal elements in such a state as to substitute for a part of the rare earth elements, the effects of the present invention can be ensured. Namely, with the one containing rare earth elements (one or more of rare earth elements) in a total amount of 1.0% or more, and having a total content of one or more of elements selected from the rare earth elements and refractory metal elements of 2.0 to 15.0%, the inconvenience when only refractory metal elements are contained therein is avoided. This can result in a reflective film capable of attaining the objects of the present invention.

The total content of rare earth elements and refractory metal elements when they are used in combination is required to be set at 2.0 to 15.0% (preferably 3.0 to 14.0%, and more preferably 4.0 to 13.0%). However, the content of rare earth elements is required to be ensured to be 1.0% or more. Incidentally, the content of rare earth elements is desirably set at preferably 1.25% or more, and is desirably set at more preferably 1.5% or more. Incidentally, in the Al-based alloy forming the reflective film of the present invention, (the balance) other than the alloy elements (rare earth elements, or rare earth elements and refractory metal elements) includes Al and inevitable impurities (e.g., Fe, Si, C, and O).

In the reflective film of the present invention, the crystallite size in the thickness direction of the reflective film is 30 nm or less, preferably 20 nm or less, and more preferably 10 nm or less. By setting the crystallite size in the thickness direction of the reflective film at 30 nm or less, the precision for the reflective film surface to reproduce the substrate shape is enhanced. As a result, the noise can be made extremely small.

The reflective film including the Al-based alloy as described above can implement a favorable reflectivity. In addition, by equipping an optical information recording medium with such a reflective film, it is possible to reduce the noise of the optical information recording medium. Other configurations in the optical information recording medium including such a reflective film (e.g., substrate and light transmission layer) have no particular restriction. Known configurations in the field of an optical information recording medium can be adopted.

The thickness of the reflective film may be appropriately set according to the kind of the optical information recording medium to which the reflective film is applied. For example, when the reflective film is used as the reflective layer of a single-layer DVD-ROM or the total reflective layer of a dual-layer DVD-ROM, the film thickness is preferably set at about 50 to 250 nm. Whereas, when the reflective film is used as the semi-transmissive reflective layer of a dual-layer DVD-ROM, the film thickness is preferably set at about 5 to 15 nm. In this case, as the total reflective layer, Al, Ag, or an alloy thereof is preferably used.

When the reflective film is used as the reflective film of a single-layer DVD-R or a single-layer DVD+R, or the total reflective layer of a dual-layer DVD-R or a DVD+R, the film thickness is preferably set at about 50 to 250 nm. When the reflective film is used as the semi-transmissive layer of a dual-layer DVD-R or a dual-layer DVD+R, the film thickness is preferably set at about 10 to 30 nm. As the recording layer used at this step, a dye layer (organic dye material layer) is preferably used. The reflective film (reflective layer) of the present invention is preferably stacked adjacent to the dye layer, and is preferably set on the backside of the dye as seen from the reproduction laser incident surface.

When the reflective film is used as the reflective layer of a single-layer BD-ROM or the total reflective layer of a dual-layer BD-ROM, it is preferably used with a film thickness within the range of about 15 to 100 nm, and can be used as the semi-transmissive reflective layer of a dual-layer BD-ROM. As the 0.1 μm transparent protective layer formed on the reproduction laser incident side, a UV-curable resin or polycarbonate is preferably used.

When the reflective film is used as the reflective layer of a single-layer BD-R or the total reflective layer of a dual-layer BD-R, the film thickness is preferably set at about 50 to 200 nm, and can be used as the semi-transmissive reflective layer of a dual-layer BD-R. As the recording layer used at this step, mention may be made of a metal oxide, a metal nitride, a dye, or the like. As the protective layers inserted on and under the recording layer, ZnS, SiO₂, a mixture thereof, Al₂O₃, or the like is preferable.

When the reflective film is used as the reflective layer of a single-layer DVD-RW, a single-layer DVD+RW, a single-layer DVD-RAM, a single-layer BD-RE, or the like, or the total reflective layer of a dual-layer BD-RE, the film thickness is preferably set at about 50 to 200 nm, and can be used as the semi-transmissive reflective layer of a dual-layer BD-RE. As the recording layer used at this step, a chalcogenide compound type material of a phase change material is preferable. Mention may be made of Ge—Sb—Te, Ag—In—Sb—Te, or the like.

The Al-based alloy reflective film of the present invention is deposited by sputtering or vapor deposition using a sputtering target including an Al-based alloy on the surface of a polycarbonate (PC) or other substrate surface. When the sputtering target used at this step includes an Al-based alloy with the same composition as that of the Al-based alloy of the present invention, the Al-based alloy reflective film with the inventive composition becomes likely to be obtained.

### EXAMPLES

Below, the present invention will be described more specifically by way of examples. However, the present invention is naturally not limited by the following examples. Appropriate changes may be made within the scope adaptable to the gist described above and below to execute the present invention. These are included in the technical scope of the present invention.

On a glass substrate or on a BD-R substrate made of polycarbonate, various Al-based alloy thin films (Tables 1 and 2 described later) were deposited by a DC magnetron sputtering method, using an alloy target, or a composite target of a pure Al target on which an additional element chip is mounted. The sputtering conditions at this step are as described below.

(Sputtering Conditions)

Sputtering device: “SIH-S100” manufactured by ULVAC, Inc.,
Target size: diameter 6 inch
Ultimate vacuum degree: 3.0×10⁻⁶ Torr (4.0×10⁻⁴ Pa) or less
Ar gas pressure: 3 mTorr (0.4 Pa)
Sputtering electric power: 400 W

The composition of each formed Al-based alloy reflective film was determined by an inductively coupled plasma (ICP) mass spectrometry.

Each formed Al-based alloy reflective film was measured for the crystallite size, the noise (noise of the recording medium), and the reflectivity with the following respective methods, respectively. In addition, for some of them, transmission electron microscope (TEM) observation of each cross section was performed.

(Crystallite Size Measurement)

On a glass substrate, an Al alloy reflective film with a film thickness: 150 nm was deposited. Thus, an X-ray diffraction measurement (θ/2θ scanning) was performed. As a result, the crystallite size (crystal grain size in the thickness direction) was calculated from the half width of the Al (111) peak of the main peak. The analysis conditions at this step were as follows.

[Analysis Conditions]

Analyzer: X-ray diffraction device “RINt-1500” manufactured by Rigaku Corp.;

Target: Cu;

Production of monochrome: monochromator is used (CuKα);

Target output: 40 kV-200 mA;

Slit: divergence 1′, scattering 1′, light reception 0.15°;

Monochromator light entrance slit: 0.6 mm;

Scanning speed: 2°/min; and

Sampling width: 0.02°

(Measurement of Noise)

On a BD-R substrate made of polycarbonate (thickness 1.1 mm, track pitch 0.32 μm, groove width: 0.16 μm, and groove depth: 25 nm), an Al-based alloy reflective film (film thickness: 100 nm) was deposited. As a cover layer, BRD-130 manufactured by NIPPON KAYAKU Co., Ltd., was applied, and cured with ultraviolet ray irradiation. The noise (unit dB) of the disk thus manufactured was measured at a frequency: 4.12 MHz using an optical disk evaluation device (“ODU-1000” manufactured by Pulsetec Industrial Co., Ltd., laser wavelength: 405 nm, NA (numerical aperture): 0.85), and a spectrum analyzer (R3131A manufactured by Advantest Corp.). At this step, the disk rotation speed was set at 4.9 m/sec in linear speed, and the reproduction laser power was set at 0.3 mW. As for the noise, the case of −51 dB or less was rated as “A”, and the case of more than −51 dB was rated as “B”.

(Measurement of Reflectivity)

On a glass substrate, a 150-nm Al-based alloy reflective film was deposited. The absolute reflectivities at wavelengths: 405 nm and 650 nm were determined using a V-570 visible/UV spectrophotometer manufactured by JASCO Corp.

(Cross-Section TEM Observation)

On a BD-R substrate made of polycarbonate (thickness 1.1 mm, track pitch 0.32 μm, groove width: 0.16 μm, and groove depth: 25 nm), an Al-based alloy reflective film (film thickness: 100 nm) was deposited. Thus, cross-section TEM observation was performed. At this step, observation was performed under a condition of an acceleration voltage: 200 kV using a field-emission type transmission electron microscope “HF-2200” manufactured by Hitachi Ltd., as the device.

The measurement results are shown with the chemical component compositions of the Al-based alloy reflective films in Tables 1 and 2 below. Incidentally, in Tables 1 and 2, when no peak occurs due to the very small crystallite size, and hence the crystallite size cannot be calculated, the crystallite size is described as “microcrystal”. Whereas, a crystallite size of 30 nm or less is rated as “A”; and a crystallite size of more than 30 nm is rated as “B”. As for the reflectivity, the case where the reflectivities at wavelengths: 405 nm and 650 nm are 65% or more is rated as “A”; and the case of less than 65% is rated as “B”. Further, in Tables 1 and 2, the column of overall evaluation is provided. A sample acceptable in all the respective characteristics is given “A”, and a sample unacceptable in any of the respective characteristics is given “B”.

TABLE 1

| Sample | | Crystallite size | | Noise | | Reflectivity (405 nm) | | Reflectivity (650 nm) | | Overall |
|---|---|---|---|---|---|---|---|---|---|---|
| No. | Composition (at %) | (nm) | Evaluation | (dB) | Evaluation | (%) | Evaluation | (%) | Evaluation | evaluation |
| 1 | Pure Al | 66 | B | −24.7 | B | 85.0 | A | 88.4 | A | B |
| 2 | Al—1.0La | 42 | B | −43.3 | B | 88.1 | A | 87.5 | A | B |
| 3 | Al—0.6Nd | 31 | B | −50.4 | B | 89.5 | A | 88.6 | A | B |
| 4 | Al—22.3La | Microcrystal | A | −52.1 | A | 62.4 | B | 64.2 | B | B |
| 5 | Al—3.8Ti | 45 | B | −41.1 | B | 83.5 | A | 83.9 | A | B |
| 6 | Al—8.2Ti | 32 | B | −50.1 | B | 77.2 | A | 78.8 | A | B |
| 7 | Al—15.6Ti | Microcrystal | A | −51.8 | A | 60.3 | B | 62.6 | B | B |
| 8 | Al—6.1La—10.4Ta | Microcrystal | A | −55.2 | A | 61.5 | B | 63.6 | B | B |
| 9 | Al—20.2La—6.2Ti | Microcrystal | A | −53.9 | A | 58.4 | B | 59.1 | B | B |
| 10 | Al—2.0Ta | 47 | B | −42.8 | B | 81.0 | A | 84.7 | A | B |
| 11 | Al—10.0Ta | 41 | B | −47.1 | B | 68.7 | A | 71.0 | A | B |
| 12 | Al—21.8Ta | Microcrystal | A | −54.1 | A | 54.4 | B | 56.3 | B | B |
| 13 | Al—15.4V | Microcrystal | A | −51.9 | A | 58.7 | B | 57.5 | B | B |
| 14 | Al—11.5Mo | 35 | B | −50.8 | B | 63.1 | B | 62.5 | B | B |
| 15 | Al—0.8Tb—6.4Ti | 31 | B | −50.2 | B | 77.4 | A | 79.0 | A | B |
| 16 | Al—1.1Nd—0.3Ta | 42 | B | −45.3 | B | 87.2 | A | 87.1 | A | B |
| 17 | Al—1.0Tm—0.3Ti | 32 | B | −48.0 | B | 88.9 | A | 88.0 | A | B |

TABLE 2

| Sample | | Crystallite size | | Noise | | Reflectivity (405 nm) | | Reflectivity (650 nm) | | Overall |
|---|---|---|---|---|---|---|---|---|---|---|
| No. | Composition (at %) | (nm) | Evaluation | (dB) | Evaluation | (%) | Evaluation | (%) | Evaluation | evaluation |
| 18 | Al—8.9La | Microcrystal | A | −54.4 | A | 80.2 | A | 82.4 | A | A |
| 19 | Al—4.4Nd | 8 | A | −52.6 | A | 83.6 | A | 85.2 | A | A |
| 20 | Al—8.7Nd | Microcrystal | A | −53.3 | A | 74.7 | A | 77.6 | A | A |
| 21 | Al—6.0Sm | 8 | A | −52.4 | A | 84.3 | A | 85.3 | A | A |
| 22 | Al—3.3Y | 23 | A | −54.2 | A | 87.5 | A | 87.6 | A | A |
| 23 | Al—2.4Ce—5.1Pr | Microcrystal | A | −53.7 | A | 81.6 | A | 80.7 | A | A |
| 24 | Al—3.1Eu—0.7Gd | 12 | A | −53.3 | A | 85.4 | A | 86.1 | A | A |
| 25 | Al—1.1Tb—3.5Dy | 9 | A | −54.5 | A | 83.9 | A | 83.0 | A | A |
| 26 | Al—3.6Ho—3.0Tm | Microcrystal | A | −54.7 | A | 82.3 | A | 82.8 | A | A |
| 27 | Al—5.9Yb | 10 | A | −53.4 | A | 83.8 | A | 84.5 | A | A |
| 28 | Al—1.5Nd—7.7Ti | 28 | A | −51.3 | A | 72.9 | A | 75.9 | A | A |
| 29 | Al—3.5Pr—7.9Ti | Microcrystal | A | −53.5 | A | 68.1 | A | 69.2 | A | A |
| 30 | Al—1.8Sm—8.9Ti | 25 | A | −52.8 | A | 69.3 | A | 71.4 | A | A |
| 31 | Al—1.4Eu—8.6Ti | 23 | A | −52.4 | A | 70.3 | A | 71.8 | A | A |
| 32 | Al—5.6Tb—7.7Ti | Microcrystal | A | −54.0 | A | 67.4 | A | 67.2 | A | A |
| 33 | Al—9.1La—3.1Ti | Microcrystal | A | −53.1 | A | 72.1 | A | 74.4 | A | A |
| 34 | Al—1.6Dy—8.6Ta | 27 | A | −53.2 | A | 70.1 | A | 71.5 | A | A |
| 35 | Al—1.2Ho—7.9Ta | 26 | A | −54.3 | A | 69.0 | A | 71.2 | A | A |
| 36 | Al—1.5Tm—8.1Ta | Microcrystal | A | −53.9 | A | 66.7 | A | 68.1 | A | A |
| 37 | Al—2.4Yb—7.3Ta | 29 | A | −54.1 | A | 65.9 | A | 67.5 | A | A |
| 38 | Al—5.9Nd—1.4Ta | Microcrystal | A | −53.9 | A | 75.3 | A | 77.0 | A | A |
| 39 | Al—6.0Nd—1.3Hf | Microcrystal | A | −52.8 | A | 71.8 | A | 72.8 | A | A |
| 40 | Al—5.6Nd—1.5W | Microcrystal | A | −53.5 | A | 74.8 | A | 76.9 | A | A |
| 41 | Al—5.0Sm—5.0Mo | 8 | A | −53.4 | A | 72.7 | A | 74.5 | A | A |
| 42 | Al—2.0Gd—10.0Nb | 15 | A | −53.9 | A | 65.3 | A | 67.2 | A | A |
| 43 | Al—2.0Ce—10.0V | Microcrystal | A | −54.6 | A | 66.5 | A | 65.9 | A | A |
| 44 | Al—6.0Nd—4.6Cr—1.0Ta | Microcrystal | A | −55.7 | A | 73.9 | A | 72.8 | A | A |
| 45 | Al—6.0Nd—5.7Ti—1.0Ta | Microcrystal | A | −54.8 | A | 68.4 | A | 69.9 | A | A |
| 46 | Al—6.0Nd—3.3La—1.0Ta | Microcrystal | A | −54.9 | A | 65.4 | A | 66.1 | A | A |

As apparent from the results, with those satisfying the requirements specified in the present invention (sample Nos. 18 to 46 of Table 2), the refinement of the crystallite size is achieved, and hence the noise can be reduced, and the high reflectivity can be kept. In contrast, with those departing from the requirements specified in the present invention (sample Nos. 1 to 17 of Table 1), at least either characteristic of noise and reflectivity is deteriorated.

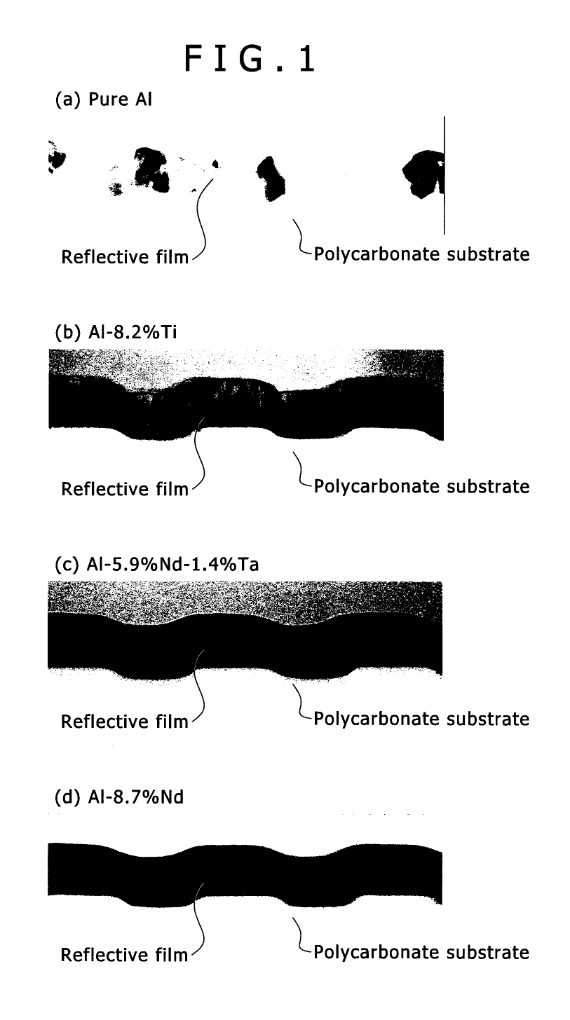

FIGS. 1(a) to 1(d) show cross-section TEM images (figure-substitute transmission electron microphotographs) of pure Al (sample No. 1 of Table 1), Al-8.2% Ti (sample No. 6 of Table 1), and Al-5.9% Nd-1.4% Ta (sample No. 38 of Table 2), and Al-8.7% Nd (sample No. 20 of Table 2), respectively, (in the figures, “%” means “at %”). In respective figures, as shown respectively, the one shown in the lower part in the figure is a polycarbonate substrate. The film formed on the polycarbonate substrate represents the reflective film.

From the results, it can be considered as follows. First, in the pure Al (FIG. 1(a)), large crystal grains are formed. Accordingly, the structure of the reflective film surface is disturbed, so that the film surface and the substrate are different in shape from each other. Whereas, in the Al-8.2% Ti (FIG. 1(b)), the crystallite size is smaller than that of pure Al. However, the crystallite has a shape long in the depth direction. Accordingly, the reflective film surface has unevenness, and cannot be said to reproduce the substrate shape with precision. On the other hand, in the Al-5.9% Nd-1.4% Ta (FIG. 1(c)), and the Al-8.7% Nd (FIG. 1(d)), the crystallite size is refined in the in-plane direction and the depth direction. Thus, the grain size is so small as not to be able to identify crystal grains even in TEM observation. Thus, the reflective film surface reproduces the substrate shape truly.

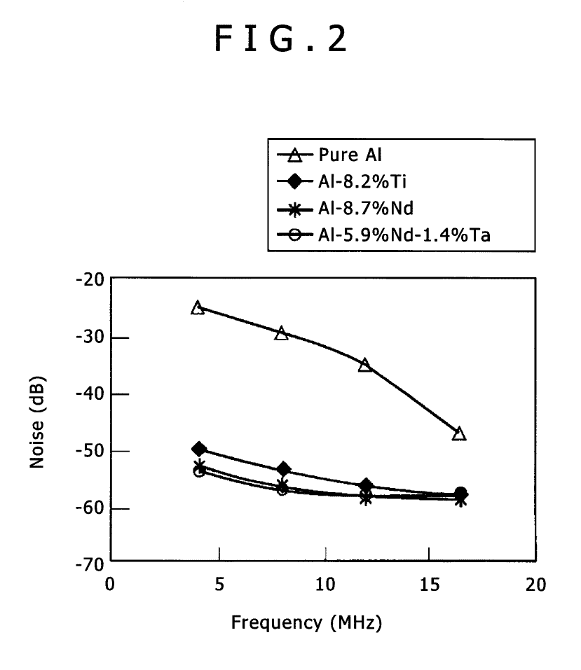

The BD-R disks manufactured using various Al alloy reflective films shown in Table 1 were measured for the noise in the same manner as described above, except for changing the frequency within the range of 4.12 to 16.5 MHz (4.12 MHz, 8.0 MHz, 12.0 MHz, and 16.5 MHz). The results are shown in Table 3 below and FIG. 2, and indicate the following. It is observed that those having a small crystallite size tend to be reduced in noise according to the crystallite size of each composition.

### [Table 3]

| Frequency | Noise (dB) | | | |
|---|---|---|---|---|
| (MHz) | Pure Al | Al—8.2Ti | Al—8.7Nd | Al—5.9Nd—1.4Ta |
| 4.12 | −24.7 | −50.1 | −53.3 | −53.9 |
| 8.0 | −29.0 | −53.7 | −56.2 | −57.0 |
| 12.0 | −35.0 | −56.6 | −58.2 | −57.9 |
| 16.5 | −47.4 | −58.3 | −59.1 | −58.3 |

The present application was described in details, and by reference to specific embodiments. However, it is apparent to those skilled in the art that various changes and modifications may be made without departing from the spirit and scope of the present invention.

The present application is based on Japanese Patent Application No. 2008-228902 filed on Sep. 5, 2008, the contents of which are incorporated herein by reference.

### INDUSTRIAL APPLICABILITY

In accordance with the present invention, it is possible to implement a reflective film capable of reducing the noise of an optical information recording medium, and having a high reflectivity. The optical information recording medium including such a reflective film is very useful for a further improvement of the recording characteristics.

1. A reflective film for optical information recording medium for use in an optical information recording medium,
the reflective film substantially comprising an Al-based alloy comprising a rare earth element in an amount of 2.0 to 15.0 at %,
the crystallite size in the thickness direction of the reflective film being 30 nm or less.

2. A reflective film for optical information recording medium for use in an optical information recording medium,
the reflective film substantially comprising an Al-based alloy comprising a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %,
the crystallite size in the thickness direction of the reflective film being 30 nm or less.

3. A sputtering target for forming a reflective film for an optical information recording medium for forming a reflective film for use in an optical information recording medium,
the sputtering target substantially comprising an Al-based alloy comprising a rare earth element in an amount of 2.0 to 15.0 at %.

4. A sputtering target for forming a reflective film for an optical information recording medium for forming a reflective film for use in an optical information recording medium,
the sputtering target substantially comprising an Al-based alloy comprising a rare earth element in an amount of 1.0 at % or more, and one or more elements selected from a group consisting of Ti, V, Cr, Nb, Mo, Hf, Ta, and W in a total amount with the rare earth element of 2.0 to 15.0 at %.
